(19) United States
(12) Patent Application Publication
(10) Pub. No.: US 2013/0169452 A1
(43) Pub. Date: Jul. 4, 2013

(54) SENSING APPARATUS UTILIZING CHARACTER/STRING SIGNAL AND SENSING SYSTEM IMPLEMENTING SENSING APPARATUS

(71) Applicant: Jui-Hsiang Fang, Taipei (TW)

(72) Inventor: Jui-Hsiang Fang, Taipei (TW)

(21) Appl. No.: 13/342,297

(22) Filed: Jan. 3, 2012

(51) Int. Cl. H03M 11/00

(52) U.S. Cl. 341/22

(57) ABSTRACT

A sensing apparatus and a sensing system implementing the sensing apparatus are provided. The sensing apparatus according to the invention includes a sensing device, a wireless signal transmitting device and a character/string signal generating device. The character/string signal generating device is for generating a character signal or a string signal in response to activation of the sensing device, and transmitting the character signal or the string signal through the wireless signal transmitting device in a wireless transmission protocol.

### BACKGROUND OF THE INVENTION

1. Field of the Invention

This present invention relates to a sensing apparatus and a sensing system, and particularly relates to the sensing apparatus and the sensing system having the sensing apparatus employing character/string signal.

2. Description of the Prior Art

The modern lives demand more security than ever in various environments, e.g. household, educational institution, factory, office building, etc. A sensing apparatus is usually implemented in those environments to detect the smoke or gas for alerting the public people or security guards. The conventional sensing devices are typically stand-alone machines that can not communicate with other electronic equipments. Along with development of communication technology, some sensors communicating with host machine via wireless transmission protocol (e.g., IEEE 802.15.4) are developed recently. However, due to higher cost of the sensing apparatus with capability of wireless transmission protocol, those sensing apparatus do not gain popularity in the market in a desired speed.

### SUMMARY OF THE INVENTION

In accordance with one aspect of the invention, a sensing apparatus including a sensing device, a wireless signal transmitting device and a character/string signal generating device is provided. The character/string signal generating device is electrically connected to the sensing device and the wireless signal transmitting device. The character/string signal generating device functions to respond actuation of the sensing device for generating a character signal or a string signal. The wireless signal transmitting device transmits the character signal or the string signal by a wireless transmission protocol. The character signal or the string signal represents the abnormal status of environment or actuation state of monitored environment.

In accordance with one embodiment, a sensing system including a sensing apparatus and a host machine is provided. The sensing apparatus includes a sensing device, a wireless signal transmitting device and a character/string signal generating device. The character/string signal generating device is electrically connected to the sensing device and the wireless signal transmitting device. The character/string signal generating device functions to respond actuation of the sensing device for generating a character signal or a string signal. The wireless signal transmitting device transmits the character signal or the string signal via a wireless transmission protocol. The host machine includes a wireless signal receipt device and a processor. The processor is electrically connected to the wireless signal receipt device. The processor functions to receive the character signal or the string signal via the wireless signal receipt device and translates the character signal or the string signal into a corresponding character or a string. The character or the string represents the abnormal status of environment or actuation state of monitored environment.

More details of the respective embodiments can be found in the respective iterations in the dependent claims hereinafter recited.

All aspects of the present invention will no doubt become apparent to those of ordinary skills in the art after reading the following detailed description of the preferred embodiment, which is illustrated in the following figures and drawings.

### BRIEF DESCRIPTION OF THE APPENDED DRAWINGS

FIG. 1 discloses a preferred embodiment of sensing apparatus;

FIG. 2 discloses a preferred embodiment of sensing system.

### DETAILED DESCRIPTION OF THE INVENTION

Some preferred embodiments and practical applications of this present invention would be explained in the following paragraph, describing the characteristics, spirit and advantages of the invention.

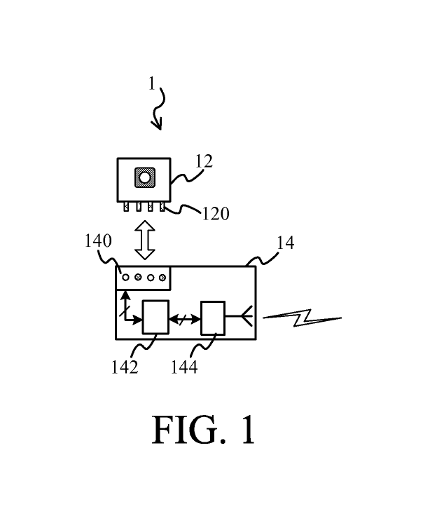

As shown in FIG. 1, the sensing apparatus 1 includes a sensing device 12, a wireless signal transmitting device 144 and a character/string signal generating device 142. The character/string signal generating device 142 is electrically connected to the sensing device 12 and the wireless signal transmitting device 144.

In a preferred embodiment, the sensing device 12 is a micro switch, a reed switch, a push_button switch, an infra-red sensor, a light switch, a temperature sensor, a smoke/gas sensor or other commercialized sensing device.

The character/string signal generating device 142 functions to respond actuation of the sensing device 12 and generate a character signal or a string signal. And the character signal or the string signal is outputted by the wireless signal transmitting device 144 via a wireless transmission protocol. The character signal or the string signal is representative of the abnormal status of environment or actuation state of monitored environment monitored by the sensing device 12.

In a preferred embodiment, the wireless transmission protocol might be 27 MH fast RF protocol, 2.4 GHz wireless protocol, 2.4 GHz Bluetooth protocol, 4.8 GHz wireless protocol, 4.8 GHz Bluetooth protocol, 9.6 GHz wireless protocol, 9.6 GHz Bluetooth protocol or other commercialized wireless transmission protocol.

In a preferred embodiment, as indicated in FIG. 1, the wireless signal transmitting device 144 and the character/string signal generating device 142 are integrated into a wireless keyboard apparatus 14. That is to say, utilizing commercialized IC chip for wireless keyboard to realize a wireless keyboard circuit board can easily produce the wireless keyboard apparatus 14.

In a preferred embodiment, the sensing device 12 is plug-and-play electrically connected to the wireless keyboard apparatus 14. As indicated in FIG. 1, the sensing device 12 includes the male connector 120. And the wireless keyboard apparatus 14 includes a corresponding female connector 140 for insertion of the male connector 120.

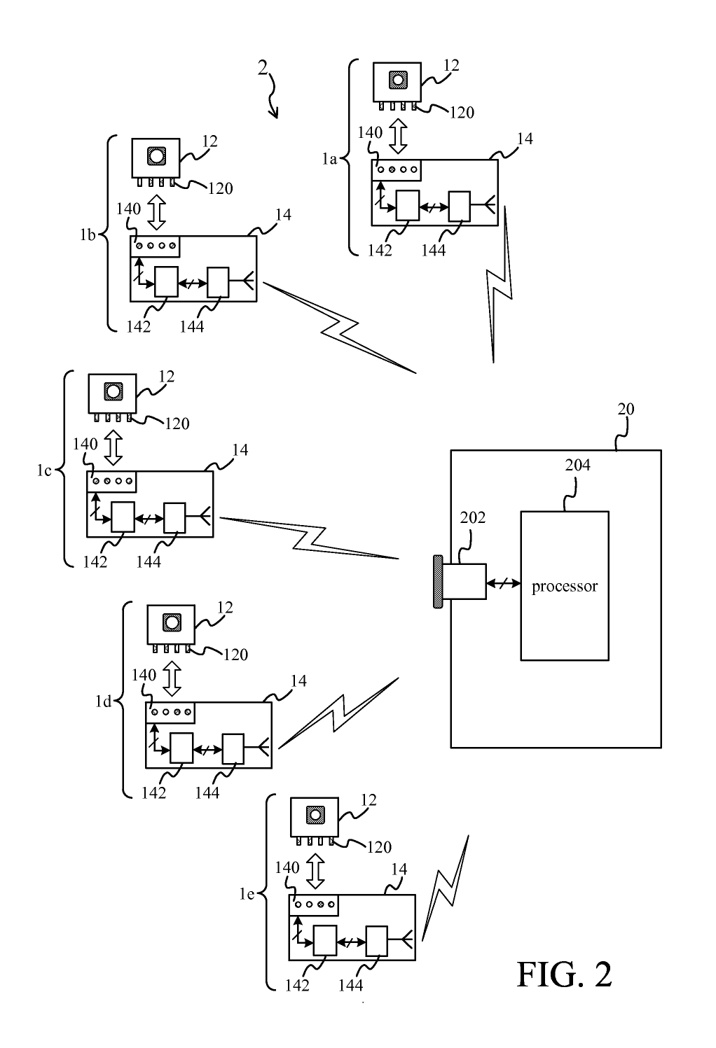

As shown in FIG. 2, the sensing system 2 includes at least one sensing apparatus (1a˜1e), for instance, and a host machine 20.

Same as or similar to the sensing apparatus 1 of FIG. 1, each sensing apparatus (1a˜1e) includes a sensing device 12, a wireless signal transmitting device 144 and a character/string signal generating device 142. The character/string signal generating device 142 is electrically connected to the sensing device 12 and the wireless signal transmitting device 144. The character/string signal generating device 142 functions to respond actuation of the sensing device 12 for generating a character signal or a string signal. And the character signal or the string signal is transmitted by the wireless signal transmitting device 144 using a wireless transmission protocol.

In a preferred embodiment, each sensing device 12 might be a micro switch, a reed switch, a push_button switch, an infra-red sensor, a light switch, a temperature sensor, a smoke/gas sensor or other commercialized sensing device. In FIG. 2, the sensing device 12 of sensing apparatus 1a is a micro switch, the sensing device 12 of sensing apparatus 1b is an infra-red sensor, the sensing device 12 of sensing apparatus 1c is a light switch, the sensing device 12 of sensing apparatus 1d is a temperature sensor and the sensing device 12 of sensing apparatus 1e is a smoke/gas sensor.

As shown in FIG. 2, the host machine 20 includes a wireless signal receipt device 202 and a processor 204. The processor 204 is electrically connected to the wireless signal receipt device 202. The processor 204 functions to receive the character signal or the string signal through the wireless signal receipt device 202 employing the wireless transmission protocol and translate the character signal or the string signal translate into a corresponding character or a string. The character or the string is representative of the abnormal status of environment or actuation state of monitored environment monitored by the sensing device 12. By the information of character or string, the sensing apparatus (1a˜1e) could directly indicate which sensing device 12 detecting abnormal environment. For instance, the string might be “right window of main bedroom is open”. The host machine 20 may be connected to an Internet network, not shown in FIG. 2, through which the monitored status of environment is transmitted to a mobile device of the user, such as Smartphone. During the process of information transmission, it is preferred that no complicated data addition is made and therefore the entire process is speedy.

In a preferred embodiment, the wireless transmission protocol might be 27 MH fast RF protocol, 2.4 GHz wireless protocol, 2.4 GHz Bluetooth protocol, 4.8 GHz wireless protocol, 4.8 GHz Bluetooth protocol, 9.6 GHz wireless protocol, 9.6 GHz Bluetooth protocol or other commercialized wireless transmission protocol. For example, as shown in FIG. 2, the wireless signal receipt device 202 might be the dongle in compliance with 2.4 GHz Bluetooth protocol.

In a preferred embodiment, as shown in FIG. 2, the wireless signal transmitting device 144 and character/string signal generating device 142 of each sensing apparatus (1a˜1e) are integrated into a wireless keyboard apparatus 14. That is to say, utilizing commercialized IC chip for wireless keyboard to realize a wireless keyboard circuit board can easily produce the wireless keyboard apparatus 14. Each sensing device 12 is plug-and-play electrically connected to a wireless keyboard apparatus 14. Each sensing device 12 includes a male connector 120 and each wireless keyboard apparatus 14 includes a corresponding female connector 140 for corresponding insertion of the male connector 120. In other words, the wireless keyboard apparatus 14 can be a module type coping with different sensing device 12.

By the above recitations, it is well understood that sensing apparatus and sensing system of the instant invention actually implements matured, low-cost character/string signal generating technology and wireless signal transmission technology to communicate with host machine. On the other hand, the sensing apparatus and sensing system provided could instantly, directly inform the user of which sensing device has detected abnormal environment.

With the example and explanations above, the features and spirits of the invention will be hopefully well described. It is understood that the invention is not only limited to those described embodiments and it is highly possible for persons skilled in the arts, without departing the spirit of the invention, might make various alteration, modification or equivalent transformation.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A sensing apparatus, comprising:
a sensing device;
a wireless signal transmitting device; and
a character/string signal generating device, respectively electrically connected to the sensing device and the wireless signal transmitting device, and responsive to actuation of the sensing device, for generating a character signal or a string signal, the wireless signal transmitting device transmitting the character signal or the string signal via a wireless transmission protocol.

2. The sensing apparatus of claim 1, wherein the wireless transmission protocol is selected from a group consisting of 27 MH fast RF protocol, 2.4 GHz wireless protocol, 2.4 GHz Bluetooth protocol, 4.8 GHz wireless protocol, 4.8 GHz Bluetooth protocol, 9.6 GHz wireless protocol and 9.6 GHz Bluetooth protocol.

3. The sensing apparatus of claim 2, wherein the wireless signal transmitting device and the character/string signal generating device are integrated into a wireless keyboard apparatus.

4. The sensing apparatus of claim 3, wherein the sensing device is selected from a group consisting of micro switch, reed switch, push_button switch, infra-red sensor, light switch, temperature sensor and smoke/gas sensor.

5. The sensing apparatus of claim 4, wherein the sensing device is plug-and-play electrically connected to the wireless keyboard apparatus.

6. The sensing system, comprising:
a sensing apparatus, including
a sensing device;
a wireless signal transmitting device; and
a character/string signal generating device, respectively electrically connected to the sensing device and the wireless signal transmitting device, and responsive to actuation of the sensing device, for generating a character signal or a string signal, the wireless signal transmitting device transmitting the character signal or the string signal via a wireless transmission protocol; and
a host machine, including:
a wireless signal receipt device; and
a processor, electrically connected to the wireless signal receipt device for receiving the character signal or the string signal via the wireless signal receipt device, and translating the character signal or the string signal into a corresponding character or string.

7. The sensing system of claim 6, wherein the wireless transmission protocol is selected from a group consisting of 27 MH fast RF protocol, 2.4 GHz wireless protocol, 2.4 GHz Bluetooth protocol, 4.8 GHz wireless protocol, 4.8 GHz Bluetooth protocol, 9.6 GHz wireless protocol and 9.6 GHz Bluetooth protocol.

8. The sensing system of claim 7, wherein the wireless signal transmitting device and the character/string signal generating device are integrated into a wireless keyboard apparatus.

9. The sensing system of claim 8, wherein the sensing device is selected from a group consisting of micro switch, reed switch, push_button switch, infra-red sensor, light switch, temperature sensor and smoke/gas sensor.

10. The sensing system of claim 9, wherein the sensing device is plug-and-play electrically connected to the wireless keyboard apparatus.
